(19) United States
(12) Patent Application Publication
(10) Pub. No.: US 2020/0264221 A1
(43) Pub. Date: Aug. 20, 2020

(54) Radio Frequency Antenna with Two Piece Sealing Ferrule

(71) Applicant: CTS Corporation, Lisle, IL (US)

(72) Inventors: Douglas E. Cors, Elkhart, IN (US); James M. Post, Elkhart, IN (US); Robert L. Newman, Edwardsburg, MI (US)

(73) Assignee: CTS Corporation, Lisle, IL (US)

(21) Appl. No.: 16/790,785

(22) Filed: Feb. 14, 2020

Related U.S. Application Data
(60) Provisional application No. 62/807,139, filed on Feb. 18, 2019.

(51) Int. Cl. G01R 29/08; H01Q 1/12; H01Q 1/42

(52) U.S. Cl. CPC G01R 29/0878; H01Q 1/42; H01Q 1/12

(57) ABSTRACT

A radio frequency antenna with a two-piece sealing ferrule. The antenna includes a center antenna and an outer tube surrounding the center antenna. A mounting nut surrounds and is slidable relative to the outer tube. An outer ferrule surrounds and is slidable relative to the outer tube. An inner ferrule that is separate from the outer ferrule surrounds and is fixed to the outer tube. A mating nut is secured to the mounting nut. The threading of the mounting nut and the mating nut together results in the wedging between the inner and outer ferrules which results in the exertion of a first compressive force by the inner ferrule against the outer tube for sealing the inner ferrule and the outer tube and the exertion of a second compressive force of the inner ferrule against the mating nut for sealing the inner ferrule and the mating nut.

### CROSS-REFERENCE TO RELATED APPLICATION

This patent application claims the priority and benefit of the filing date of U.S. Provisional Patent Application Ser. No. 62/807,139 filed on Feb. 18, 2020, the disclosure and contents of which are expressly incorporated herein in their entirety by reference.

### FIELD OF THE INVENTION

This invention relates generally to a radio frequency antenna and more specifically to a radio frequency signal transmitting and/or receiving antenna assembly with a two-piece sealing ferrule structure.

### BACKGROUND OF THE INVENTION

Radio frequency (RF)—and microwave-based sensing techniques, including cavity perturbation methods and the like, are used in many applications ranging from laboratory and research instrumentation to process control systems and even on-vehicle sensors. In many applications, antennas or probes are used to transmit and/or receive radio frequency or microwave signals to conduct these measurements.

Many conventional RF antennas are not robust and are incapable of surviving extended operation or replacement in the field with exposure to high temperatures, high vibration levels, thermal shock, corrosive or dirty environments, oxidizing or reducing conditions, and the like. Environmental exposure, rain, snow, and saltwater for example, as well as exposure to chemicals and solvents, such as oils, fuels, acids, and similar chemicals, is also detrimental to many conventional RF/microwave probes and antennas.

The RF antenna described herein may be used in several applications, ranging from cavities to transmission lines, and even in free space. One range of applications include systems which monitor changes in the dielectric properties of a material or a mixture of materials in order to deduce some information regarding the state of the system.

One specific example includes a class of radio-frequency measurement systems applied to monitor and sense vehicle exhaust emissions or the state of various vehicle emission control and sensor devices. Radio-frequency or microwave systems used to monitor the loading state of vehicle particulate filters, such as the amount of soot or ash accumulated in a diesel particulate filter, is one exemplary application. Another application includes the monitoring of various gaseous species, such as oxygen or oxides of nitrogen (among others), adsorbed onto various catalytic emission after treatment components, such as three-way catalytic converters, selective catalytic reduction systems, oxidation catalysts, or lean NOx traps, to name a few. In yet another embodiment, the monitored parameter may be a change in the dielectric properties of the material itself, such as the filter material in the case of a diesel particulate filter, in one example and the catalysts substrate, wash coat, or catalyst material in yet another example. Although after treatment filters and catalysts are described and are particularly challenging, any filter system or catalyst system can use the technology described herein.

The present invention is directed to an improved radio frequency antenna or measurement probe with a two-piece sealing ferrule structure adapted for facilitating and simplifying the serviceability and replacement of the radio frequency antenna in the field.

### SUMMARY OF THE INVENTION

The present invention is generally directed to a radio frequency antenna comprising a center antenna, a tube surrounding the center antenna, a mounting nut surrounding and slidable along the tube, an outer ferrule surrounding and slidable along the tube, an inner ferrule separate from the outer ferrule and surrounding and fixed to the tube, and a mating nut secured to the mounting nut, wherein the threading of the mounting nut and the mating nut together results in the exertion of a first compressive force by the inner ferrule against the tube for sealing the inner ferrule and the tube and the exertion of a second compressive force of the inner ferrule against the mating nut for sealing the inner ferrule and the mating nut.

In one embodiment, the inner ferrule and the outer ferrule include respective camming surfaces abutted and wedged against each other.

In one embodiment, the inner ferrule includes an end with an exterior camming surface and the outer ferrule includes an end with an interior camming surface, the end of the inner ferrule extending into the end of the outer ferrule into a relationship with the respective exterior and interior camming surfaces abutted and wedged against each other.

In one embodiment, the respective exterior and interior camming surfaces of the inner and outer ferrules are angled.

In one embodiment, the mating nut and the inner ferrule include respective interior and exterior radial faces abutted against each other, the threading of the mounting nut and the mating nut together results in the exertion of the second compressive force by the inner ferrule against the mating nut for providing the seal between the abutted interior and exterior radial faces of the mating nut and the inner ferrule respectively.

In one embodiment, the mating nut includes an interior shoulder defining the radial end face of the mating nut.

The present invention is also directed to a radio frequency antenna comprising a center antenna, a tube surrounding the center antenna, a mounting nut surrounding and slidable along the tube, an outer ferrule surrounding and slidable along the tube, an inner ferrule separate from the outer ferrule and surrounding and fixed to the tube, and a mating nut secured to the mounting nut, wherein the threading of the mounting nut and the mating nut together wedges the inner and outer ferrules together and results in the exertion of a first compressive force by the inner ferrule against the tube for sealing the inner ferrule and the tube and the exertion of a second compressive force of the inner ferrule against the mating nut for sealing the inner ferrule and the mating nut.

In one embodiment, the inner and outer ferrules include respective abutting camming surfaces.

In one embodiment, the inner ferrule includes an exterior camming surface and the outer ferrule includes an interior camming surface in abutting wedging relationship with the exterior camming surface of the inner ferrule.

In one embodiment, the inner ferrule includes a collar with the exterior camming surface and the outer ferrule includes an end with the interior camming surface, the collar of the inner ferrule extending into the end of the outer ferrule.

The present invention is also directed to a radio frequency antenna comprising a center antenna, a tube surrounding the center antenna, a mounting nut surrounding and adapted for sliding movement relative to the tube, an outer ferrule surrounding and adapted for sliding movement relative to the tube, an inner ferrule separate from the outer ferrule and surrounding and fixed on the tube and including a collar extending into an end of the outer ferrule and a radial end face, and a mating nut secured to the mounting nut and including an interior shoulder, wherein the threading of the mounting nut and the mating nut together results in the exertion of a first compressive force by the inner ferrule against the tube for sealing the inner ferrule and the tube and the exertion of a second compressive force between the interior shoulder of the mating nut and the radial end face of the inner ferrule for sealing the inner ferrule and the mating nut.

In one embodiment, the end of the outer ferrule includes an interior camming surface and the collar of the inner ferrule includes an exterior camming surface in abutting and wedging relationship with the interior camming surface of the outer ferrule.

In one embodiment, the respective interior and exterior camming surfaces of the outer and inner ferrules are angled.

Other advantages and features of the present invention will be more readily apparent from the following detailed description of the preferred embodiment of the invention, the accompanying drawings, and the appended claims.

### BRIEF DESCRIPTION OF THE DRAWINGS

These and other features of the invention can best be understood by the description of the accompanying FIGS. as follows:

FIG. 1 is an exploded, broken perspective view of a radio frequency antenna in accordance with the present invention;

FIG. 2 is a vertical cross-sectional view of the radio frequency antenna shown in FIG. 1;

FIG. 3 is a vertical broken cross-sectional view of the radio frequency antenna shown in FIG. 1 being inserted into the interior of a resonant cavity/housing; and

FIG. 4 is a vertical broken cross-sectional view of the radio frequency antenna secured to the resonant cavity/housing via a mating nut or boss secured to the exterior wall of the resonant cavity/housing.

### DESCRIPTION OF THE EMBODIMENT

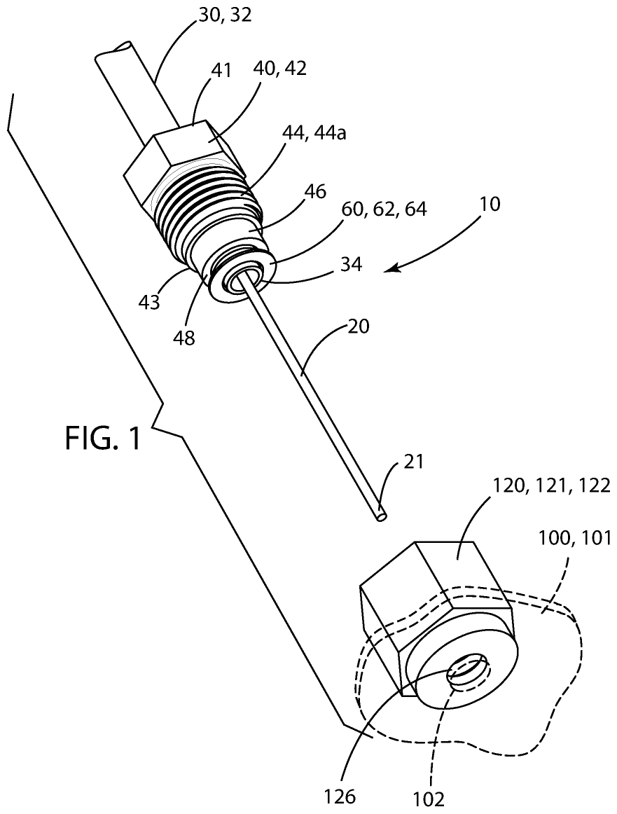

FIGS. 1, 2, 3, and 4 depict a radio frequency (RF) antenna/probe assembly or module 10 in accordance with the present invention which, in one embodiment, is a radio frequency antenna/probe of the type generally designated by the numerals 224, 230, 242, and 246 in the radio frequency vehicle exhaust control system disclosed in U.S. Pat. No. 8,384,397 and further of the type disclosed in US Published Patent Application No. US 2015/0123688 A1, the entire contents and disclosures of which are incorporated herein by reference as though fully set forth herein.

The RF antenna/probe assembly 10 in FIGS. 1, 2, 3, and 4, in one embodiment, is adapted for transmitting and receiving radio frequency signals in an RF vehicle exhaust control and sensor system that includes a resonant cavity/housing 100 and an antenna mounting nut or boss 120 that is secured to the exterior wall 101 of the cavity/housing 100 and is adapted for coupling and securing the antenna/probe 10 to the cavity/housing 100.

The RF antenna/probe assembly 10 initially comprises an inner elongate and tubular antenna 20 composed of a suitable metallic material adapted for the transmission and/or reception of radio frequency (RF) signals and adapted to be inserted and located in the interior of the resonant cavity/housing 100. The antenna 20 includes a first straight distal section or end 21 as shown in the figures and a bent second section not shown in the figures but shown in U.S. Pat. No. 10,476,142, the contents and disclosure of which are incorporated herein by reference as though fully set forth herein.

The RF antenna/probe assembly 10 further comprises an outer exterior elongate hollow tube 30 including an exterior circumferential surface or face 32 and a distal end 34. The tube 30 surrounds and is spaced from the inner antenna 20 and is composed of a suitable metal. The tube 30 includes a first straight section as shown in the figures and a bent section not shown in the figures but shown in U.S. Pat. No. 10,476,142 which is commensurate in shape to the inner antenna 20.

The RF antenna/probe assembly 10 still further comprises a tubular mounting nut 40 surrounding and adapted for rotation and sliding longitudinal movement relative to and along the length of the outer tube 30. The mounting nut 40 includes a hexagon shaped base 42 and an exteriorly threaded tubular portion or segment or neck 44 extending unitarily longitudinally outwardly from the end of the base 42 and defining an exterior thread 44a.

The RF antenna/probe assembly 10 further comprises a two-piece sealing ferrule assembly that includes a first slidable outer ferrule 46 and a separate second fixed inner ferrule 60 as described in more detail below.

The outer generally donut shaped ferrule piece or element 46 defines a central opening or aperture and which surrounds and is adapted for rotation and sliding longitudinal movement relative to the outer tube 30.

The outer ferrule 46 includes opposed distal exterior radial end faces or ends 47 and 48 and a longitudinally and circumferentially extending interior surface 50 including an interior straight portion or segment 51 and a distal generally cone shaped interior camming or angled segment or portion or surface 52 converging and angling inwardly from the distal exterior radial end face 48 in the direction of the interior straight portion or segment 51 and the distal radial end face 47.

The generally cone shaped inner ferrule piece or element 60 surrounds and is fixed or secured to the exterior circumferential surface 32 of the outer tube 30 at a location adjacent the distal radial end face 34 of the outer tube 30.

The inner ferrule 60 includes an interior circumferential face or surface 61 surrounding the exterior circumferential face or surface 32 of the outer tube 30, opposed distal radial end faces 63 and 64, a first base portion or segment or collar 62, and a second end camming portion or segment or collar 69 extending unitarily outwardly from the first base portion or segment 62.

The first base portion or segment 62 includes the distal radial end face 64 and an exterior circumferential angled surface 66 which converges and angles inwardly from the radial end face 64 in the direction of and into the second camming portion or segment 69.

The second camming portion or segment 69 includes the distal radial end face 63 and includes an exterior circumferential angled surface 68 that converges and angles inwardly from the exterior circumferential surface 66 of the first base portion or segment 62 in the direction of and into the radial end face 63 of the second camming portion or segment 69.

The RF antenna/probe assembly 10 still further comprises a mating boss or nut 120 that is secured and fixed as by welding or the like to the exterior face or surface or wall 101 of the cavity/housing 100 and is adapted for coupling and securing the RF antenna/probe assembly 10 to the cavity/housing 100.

The mating boss or nut 120 includes a circumferential hollow collar 122 including a hexagon shaped exterior surface 121 and defining an interior circumferential threaded surface 122a, an interior sealing shoulder 124 including an exterior radial surface or face 124a and extending into a through-hole or aperture or opening 102 defined in the exterior wall 101 of the cavity/housing 100, and an opening or aperture 126 defined in the center of the shoulder 124 and in communication with the interior of the cavity/housing 100.

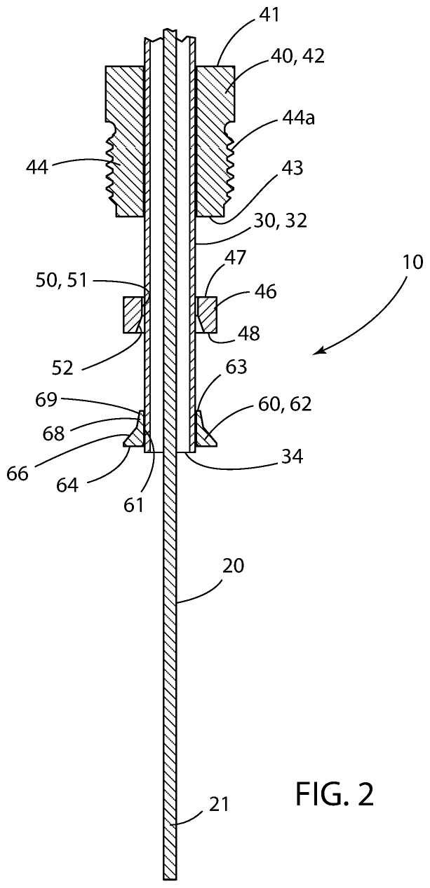

As depicted in more detail with reference to FIGS. 2, 3, and 4, the RF antenna 10 is secured to the mating boss or nut 120 and thus to the cavity/housing 100 as describe in more detail below.

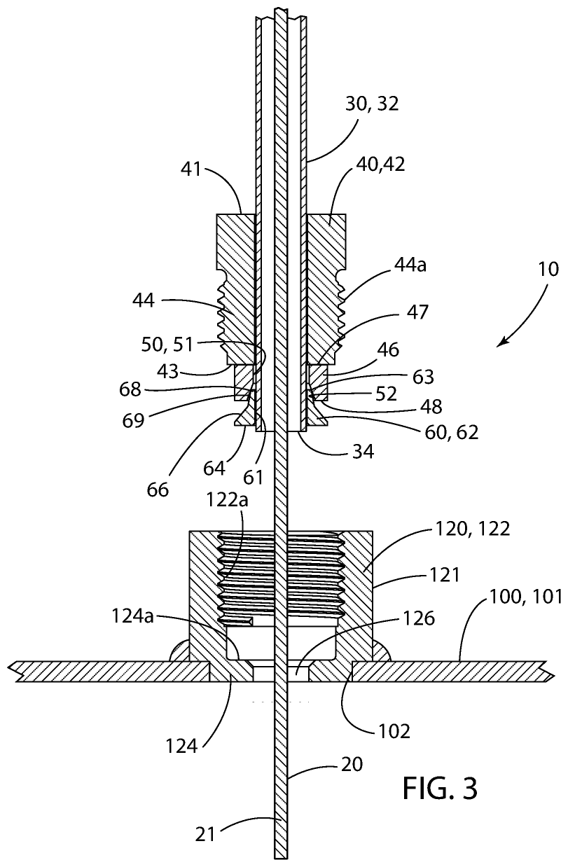

The mounting nut 40 on the RF antenna assembly 10 is slid longitudinally forwardly along the exterior surface 32 of the outer tube 30 in the direction of the inner ferrule 60 into the position as shown as shown in FIGS. 1 and 3 wherein the outer ferrule 46 is wedged and sandwiched between the inner ferrule 60 and the distal radial end face 43 of the mounting nut 40 and, more specifically, into a relationship with the exterior camming portion or segment 69 of the inner ferrule 60 extending into the radial distal end 48 and interior of the outer ferrule 46 and still, more specifically, into a relationship with the converging exterior surface or face 68 of the camming portion or segment 69 of the inner ferrule 60 in abutting relationship with and against the cone shaped converging interior surface or face 52 of the outer ferrule 46.

Thus, in the position of the RF antenna assembly 10 as shown in FIGS. 1 and 3, the outer ferrule 46 is sandwiched between the mounting nut 40 and the inner ferrule 60.

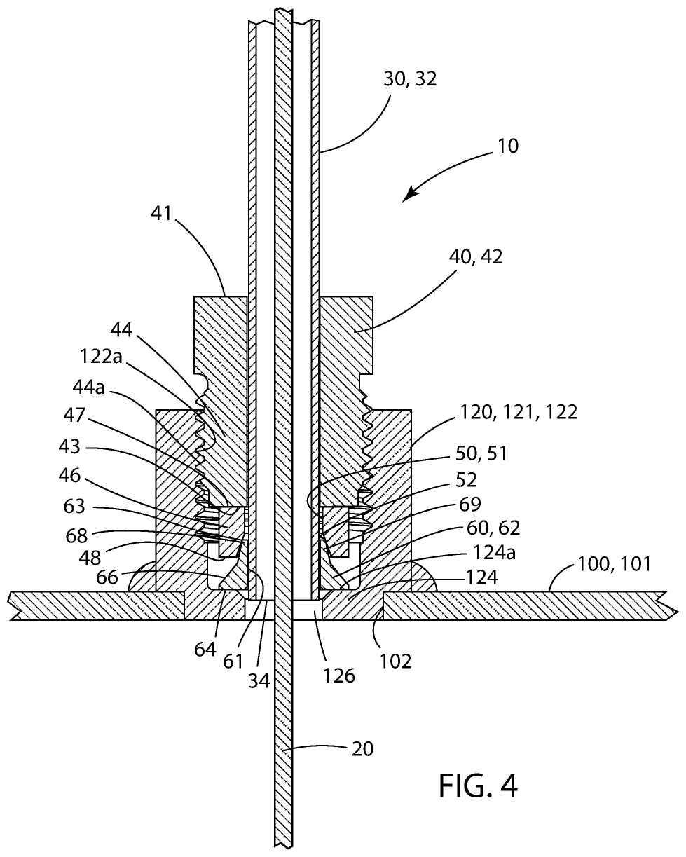

As shown in FIGS. 3 and 4, the distal end 21 of the inner antenna 20 of the RF antenna assembly 10 is inserted and extended successively through the interior of the mating boss or nut 120, through the opening 126 defined in the interior of the mating boss or nut 120 and the shoulder 124 thereof, and into the interior of the cavity/housing 100.

As also shown in FIG. 4, the mounting nut 40 is advanced and screwed onto the mating boss or nut 120 to couple the mounting nut 40 and the mating nut 129 together into a relationship with the exterior threads 44a on the neck 44 of the mounting nut 40 in threading engagement with the interior threads 122a in the collar 122 of the mating boss or nut 120.

The mounting nut 40 is advancingly further threaded onto the mating boss or nut 120 into a relationship with the radial end face 64 of the inner ferrule 60 in abutting face-to-face contact with the exterior face 124a of the interior shoulder 124 of the mating boss or nut 120.

The still continued advancement and threading of the mounting nut 40 and the mating nut 120 together results in the rearward or further inward movement of the exterior camming portion or segment 69 of the inner ferrule 60 into the interior of the outer ferrule 50 and, more specifically, results in the sliding abutting contact between the respective converging or angled interior and interior surfaces 52 and 68 of the respective outer and inner ferrules 50 and 60 which, in turn, results in the exertion of an inward compressive force by the interior camming surface 52 of the outer ferrule 50 against the interior camming surface 69 of the inner ferrule 60 which results in the exertion of a sealing force by the interior circumferential surface 61 of the inner ferrule 60 against the exterior circumferential surface 32 of the outer tube 30 to provide a first seal between the outer tube 30 and the inner ferrule 60.

The still continued advancement and threading of the mounting nut 40 and the mating nut 120 together also results in the exertion of a compressive force between the exterior face or surface 124a of the interior collar 124 of the mating boss or nut 120 and the exterior radial end face 64 of the inner ferrule 60 to provide a second seal between the mating boss or nut 120 and the inner ferrule 60.

Numerous variations and modifications of the radio frequency antenna assembly 10 described above may be effected without departing from the spirit and scope of the novel features of the invention. It is to be understood that no limitations with respect to the specific radio frequency antenna illustrated herein are intended or should be inferred. It is, of course, intended to cover by the appended claims all such modifications as fall within the scope of the claims.

What is claimed is:

1. A radio frequency antenna comprising:
a center antenna;
a tube surrounding the center antenna;
a mounting nut surrounding and slidable along the tube;
an outer ferrule surrounding and slidable along the tube;
an inner ferrule separate from the outer ferrule and surrounding and fixed to the tube; and
a mating nut secured to the mounting nut;
wherein the threading of the mounting nut and the mating nut together results in the exertion of a first compressive force by the inner ferrule against the tube for sealing the inner ferrule and the tube and the exertion of a second compressive force of the inner ferrule against the mating nut for sealing the inner ferrule and the mating nut.

2. The radio frequency antenna of claim 1 wherein the inner ferrule and the outer ferrule include respective camming surfaces abutted and wedged against each other.

3. The radio frequency antenna of claim 2 wherein the inner ferrule includes an end with an exterior camming surface and the outer ferrule includes an end with an interior camming surface, the end of the inner ferrule extending into the end of the outer ferrule into a relationship with the respective exterior and interior camming surfaces abutted and wedged against each other.

4. The radio frequency antenna of claim 3 wherein the respective exterior and interior camming surfaces of the inner and outer ferrules are angled.

5. The radio frequency antenna of claim 1 wherein the mating nut and the inner ferrule include respective interior and exterior radial faces abutted against each other, the threading of the mounting nut and the mating nut together results in the exertion of the second compressive force by the inner ferrule against the mating nut for providing the seal between the abutted interior and exterior radial faces of the mating nut and the inner ferrule respectively.

6. The radio frequency antenna of claim 5 wherein the mating nut includes an interior shoulder defining the radial end face of the inner ferrule.

7. A radio frequency antenna comprising:
a center antenna;
a tube surrounding the center antenna;
a mounting nut surrounding and slidable along the tube;
an outer ferrule surrounding and slidable along the tube;
an inner ferrule separate from the outer ferrule and surrounding and fixed to the tube; and
a mating nut secured to the mounting nut;
wherein the threading of the mounting nut and the mating nut together wedges the inner and outer ferrules together and results in the exertion of a first compressive force by the inner ferrule against the tube for sealing the inner ferrule and the tube and the exertion of a second compressive force of the inner ferrule against the mating nut for sealing the inner ferrule and the mating nut.

8. The radio frequency antenna of claim 7 wherein the inner and outer ferrules include respective abutting camming surfaces.

9. The radio frequency antenna of claim 8 wherein the inner ferrule includes an exterior camming surface and the outer ferrule includes an interior camming surface in abutting wedging relationship with the exterior camming surface of the inner ferrule.

10. The radio frequency antenna of claim 9 wherein the inner ferrule includes a collar with the exterior camming surface and the outer ferrule includes an end with the interior camming surface, the collar of the inner ferrule extending into the end of the outer ferrule.

11. A radio frequency antenna comprising:
a center antenna;
a tube surrounding the center antenna;
a mounting nut surrounding and adapted for sliding movement relative to the tube;
an outer ferrule surrounding and adapted for sliding movement relative to the tube;
an inner ferrule separate from the outer ferrule and surrounding and fixed on the tube and including a collar extending into an end of the outer ferrule and a radial end face; and
a mating nut secured to the mounting nut and including an interior shoulder;
wherein the threading of the mounting nut and the mating nut together results in the exertion of a first compressive force by the inner ferrule against the tube for sealing the inner ferrule and the tube and the exertion of a second compressive force between the interior shoulder of the mating nut and the radial end face of the inner ferrule for sealing the inner ferrule and the mating nut.

12. The radio frequency antenna of claim 11 wherein the end of the outer ferrule includes an interior camming surface and the collar of the inner ferrule includes an exterior camming surface in abutting and wedging relationship with the interior camming surface of the outer ferrule.

13. The radio frequency antenna of claim 12 wherein the respective interior and exterior camming surfaces of the outer and inner ferrules are angled.
